(19) United States
(12) Patent Application Publication
(10) Pub. No.: US 2004/0159931 A1
(43) Pub. Date: Aug. 19, 2004

(54) Electronic package, heater block and method

(75) Inventors: Alexander M. Arayata, Shelburne, VT (US); John J. Maloney, Essex Junction, VT (US)

Correspondence Address: HOFFMAN WARNICK & D'ALESSANDRO, LLC, 3 E-COMM SQUARE, ALBANY, NY, 12207

(73) Assignee: International Business Machines Corporation, Armonk, NY

(21) Appl. No.: 10/781,971

(22) Filed: Feb. 19, 2004

Related U.S. Application Data
(63) Continuation-in-part of application No. 10/108,680, filed on Mar. 27, 2002, now abandoned.

(51) Int. Cl. H01L 23/495

(52) U.S. Cl. 257/690

(57) ABSTRACT

An electronic package and method furnish shorter wire bonds for smaller chips by increasing the length of the leads and decreasing the size of the paddle. A portion of each lead is reduced in thickness such that polymeric material exposes only a portion of the lead, e.g., that portion that meets industry standards. The portion having a reduced thickness extends further from the thicker portion toward the die paddle than in conventional packages. Since the wire bonds are shorter, the electronic package exhibits less inductance and, hence, increased performance. A heater block used to fabricate the electronic package having raised heating sections for the thinner leads is also included.

This application is a continuation-in-part application of U.S. Ser. No. 10/108,680, filed Mar. 27, 2002, currently pending.

### BACKGROUND OF THE INVENTION

1. Technical Field

The present invention relates generally to electronic packages, and more particularly, to an electronic package and method that provide reduced wire bond lengths, less inductance and, hence, increased performance. In addition, this invention includes a heater block for attachment of wire bonds to the die pad and the leads.

2. Related Art

As integrated circuits (IC) become smaller, problems related to electronic packaging assembly arise. One such problem relates to the necessity to lengthen wire bonds as chip size decreases. To illustrate, an exemplary electronic package 10 in the form of a quad flatpack, no lead (QFN) configuration is shown in FIGS. 1 and 2. Electronic package 10 includes a semiconductor chip 12 mounted with an adhesive 14 to a paddle (metal layer) 16. A number of metal leads 18 surround chip 12. Chip 12 is electrically interconnected to metal layer 16 and selected metal leads 18 by wire bonds 20. The device is encapsulated in a polymeric mold compound material 22 (FIG. 1 only). As detectable in FIG. 2, the length of wire bond 20 necessary to couple chip 12 to metal leads 18 is significant. As is also noticeable in FIG. 2, as chip 12 becomes smaller, the length of wire bonds 20 from the chip to metal leads 18 must become larger.

Another problem with longer wire bonds is the increased inductance created. In particular, for radio frequency (RF) applications, increased inductance reduces performance.

An obstacle to shortening wire bond length is that it is preferable that electronic packages meet certain industry standards such as those promulgated by the JEDEC Solid State Technology Association (formerly known as the Joint Electron Device Engineering Council (JEDEC)). These standards generally set out industry acceptable parameters such as package size, lead dimensions and positioning, etc. If an electronic package does not meet these standards, the chances of the package being used widely is diminished.

Glenn et al., in U.S. Pat. No. 6,521,987, disclose a circuit device package in which lower faces of the die pad and the leads are provided with stepped profiles to prevent the leads from being pulled horizontally from the package. While Glenn et al. states that the leads can be placed close to the die to minimize the length of wire bonds, this reference provides conventional lead lengths and die paddle size. For example, a conventional lead length is 0.35 mm to 0.55 mm, and a conventional die paddle size may be 1.7 mm to 7.8 mm depending on the package size. Glenn et al. also fail to address a problem created by the thinner leads in that bonding the wire bonds to the leads is very difficult because the thinner lead ends cannot be sufficiently heated and supported with conventional techniques.

In view of the foregoing, there is a need in the art for an electronic package and method that provide shorter wire bonds for smaller chips, yet meet industry standards.

### SUMMARY OF THE INVENTION

An electronic package and method furnish shorter wire bonds for smaller chips by increasing the length of the leads and decreasing the size of the paddle. A portion of each lead is reduced in thickness such that polymeric material exposes only a portion of the lead, e.g., that portion that meets industry standards. The portion having a reduced thickness extends further from the thicker portion toward the die paddle than in conventional packages. Since the wire bonds are shorter, the electronic package exhibits less inductance and, hence, increased performance. A heater block used to fabricate the electronic package having raised heating sections for the thinner leads is also included.

A first aspect of the invention is directed to an electronic package having a mounted semiconductor chip and a polymeric material, the electronic package comprising: a metal lead having a first portion that is unexposed on a surface of the package by the polymeric material and a second portion that is exposed, the first portion having a thickness that is less than the second portion, and wherein the first portion extends no less than approximately 0.7 mm and no greater than approximately 1.0 mm from the second portion; and an electrical interconnection from the first portion to the semiconductor chip.

A second aspect of the invention provides a method of forming an electronic package, the method comprising the steps of: providing a semiconductor chip mounted to a surface of a metal layer by an adhesive; reducing the thickness of a metal lead such that the metal lead includes a first portion having a thickness that is less than a second portion; electrically interconnecting the first portion to the semiconductor chip by placing a wire bond to the first portion and heating the first portion with a heater block having a heating section extending above a support section; and enclosing at least a portion of the semiconductor chip, the surface of the metal layer and the first portion of the metal lead in a polymeric material, whereby the second portion remains exposed by the polymeric material.

A third aspect of the invention is directed to a heater block for use in fabricating an electronic package having a lead having a first portion having a thickness that is less than a second portion thereof, the heater block comprising: an electronic package support section for supporting the second portion; and a raised heating section for heating the first portion, the raised heating section extending above the support section to be adjacent the first portion.

The foregoing and other features of the invention will be apparent from the following more particular description of embodiments of the invention.

### BRIEF DESCRIPTION OF THE DRAWINGS

The embodiments of this invention will be described in detail, with reference to the following figures, wherein like designations denote like elements, and wherein:

FIG. 1 shows a cross-sectional side view of a conventional electronic package;

FIG. 2 shows a plan view of the electronic package of FIG. 1 without polymeric material;

FIG. 3 shows a cross-sectional side view of an electronic package according to the invention;

FIG. 4 shows a plan view of the electronic package of FIG. 3 without polymeric material;

FIG. 5 shows a bottom view of the electronic package of FIG. 3;

FIG. 6 shows a side view of a heater block for use in fabricating the electronic package of FIGS. 3-5; and

FIG. 7 shows a plan view of the heater block of FIG. 6.

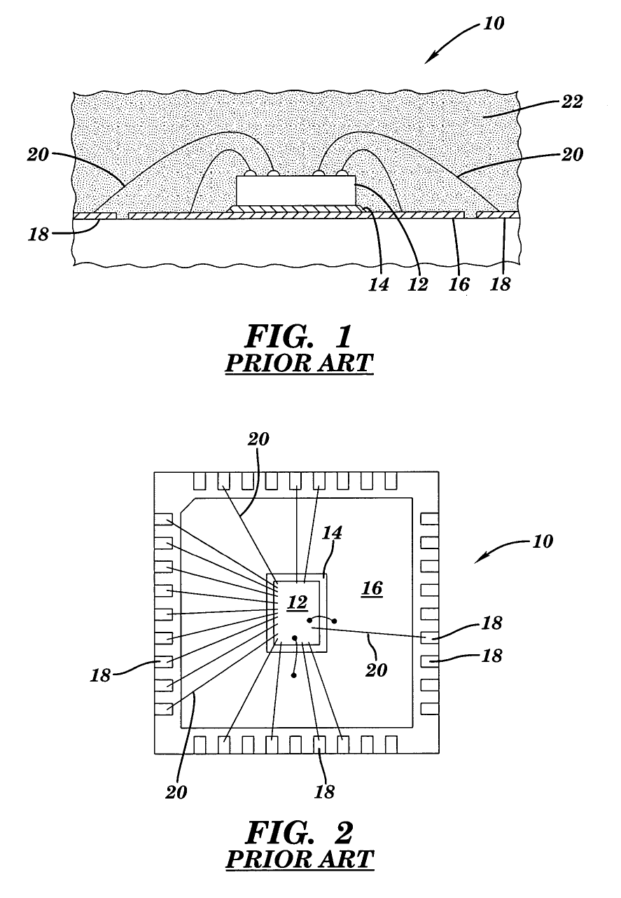

### DETAILED DESCRIPTION OF THE INVENTION

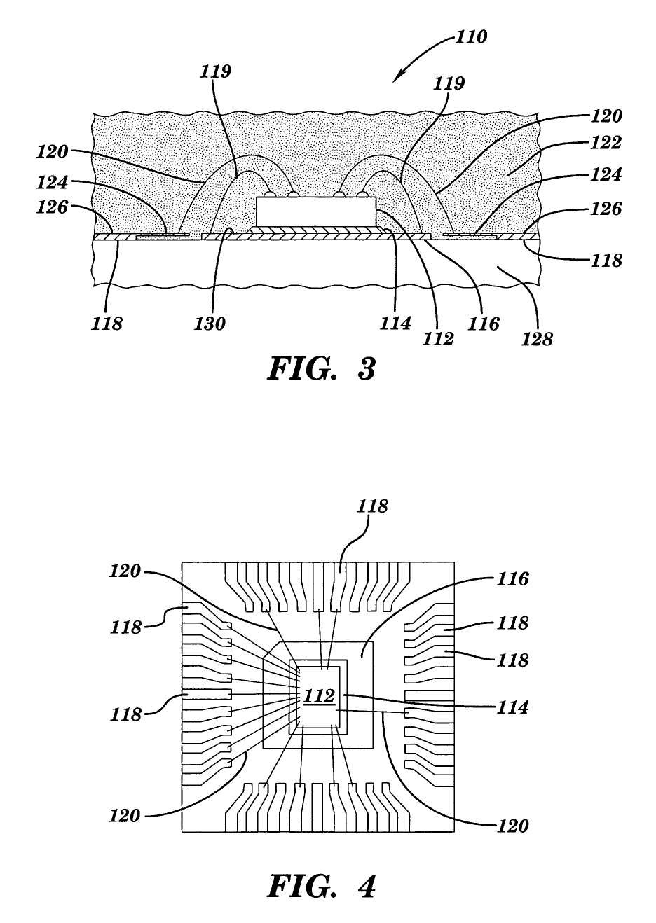

With reference to the accompanying drawings, FIGS. 3-5 illustrate an electronic package 110 according to the invention. For purposes of discussion, electronic package 110 is shown in the form of a quad flatpack, no lead (QFN) configuration. It should be recognized, however, that the teachings of the invention are applicable to a wide variety of electronic packages and that the scope of the invention should not be limited to this exemplary embodiment.

Turning to FIG. 3, electronic package 110 includes a semiconductor chip 112 mounted, with an adhesive 114, to a metal layer 116, i.e., a die paddle. Metal layer 116 may be made of, for example, copper, copper alloys, nickel alloys, etc. As shown in FIG. 4, a plurality of metal leads 118 are positioned about chip 112. Chip 112 is connected to metal layer 116 by electrical interconnections, i.e., wire bonds, 119 (FIG. 3 only). The device is encapsulated in a polymeric mold compound material 122 (FIG. 3 only). Polymeric material 122 may be any now known or later developed mold compound such as epoxy novolac, biphenyl epoxy, silicone, etc.

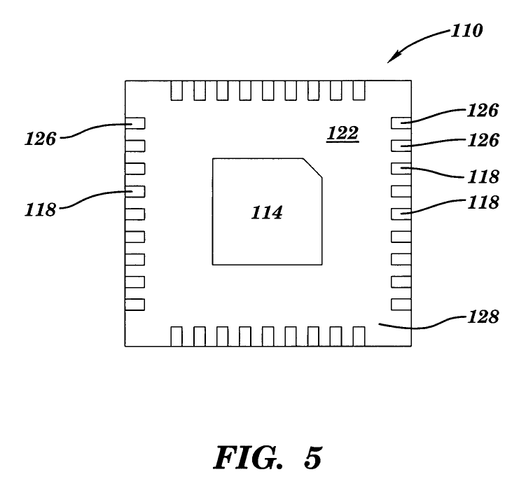

As discernible by comparing FIGS. 2 and 4, metal layer 116 (FIG. 4) is diminished in size compared to that of conventional electronic packages (16 in FIG. 2). In addition, each metal lead 118 (FIG. 4) is longer compared to conventional electronic packages (18 in FIG. 2) by approximately 30%-50%. Further, as shown in FIG. 3, each metal lead 118 includes a first portion 124 closer to chip 112 than a second portion 126. Each first portion 124 is also thinner than second portion 126. As a result, as shown in FIG. 3 and the bottom view of FIG. 5, first portion 124 is unexposed on a surface 128 of the package by polymeric material 122. In contrast, second portion 126 is exposed. In this fashion, longer leads 118 can be created that require shorter wire bonds 120, and the leads can still be sized to meet industry standards. In particular, JEDEC Solid State Technology Association specifications require that a length of exposed second portion 126 be 0.35 mm to 0.45 mm. According to the present invention, first portion 124 is extended in length to be no less than approximately 0.7 mm and no greater than approximately 1.0 mm beyond the 0.35 to 0.45 mm of second portion 126. This lengthening of lead 118 shortens the overall length of wire bonds 120, and therefore increases the RF electrical performance of the package. In one embodiment, wire bonds are no longer than approximately 4.0 mm. In addition to the lengthening of leads 118, the size of metal layer 116 may also be reduced from, for example, 3.8 mm-7.8 mm to 1.8-5.8 mm. Reducing metal layer 116 size reduces wire bond 119 length, which improves RF performance by reducing ground (GND) inductance. Chip 112 is connected to selected metal leads 118 by electrical interconnections, i.e., wire bonds 120. The wire bond lengths are approximately 0.7 mm shorter compared to conventional packages (FIG. 2). This reduction in length equates to anywhere from approximately 30%-50% reduction in overall wire bond length depending on the package size, lead pitch, and lead quantity.

The reduction in thickness of first portion 124 compared to second portion 126 can be provided by any now known or later developed process. In one embodiment, first portion 124 is etched, for example, using a common isotropic etching process. The amount of material removed to create first portion 124 can be altered according to the desire of the user and/or the properties of polymeric material 122. In one embodiment, first portion 124 has a thickness that is no less than approximately 40% and no larger than approximately 85% of second portion 126. In another embodiment, first portion 124 is approximately 50% the thickness of second portion 126, i.e., a half etch is performed on lead 118.

The invention also includes a method of forming an electronic package 110. According to the method, chip 112 is provided mounted to a surface 130 of metal layer 116 by adhesive 114. Next, the thickness of metal lead 118 is reduced (e.g., by etching) such that metal lead 118 includes first portion 124 having a thickness that is less than (e.g., 50%) second portion 126. Electrically interconnecting first portion 124 to chip 112 using a specialized heater block follows this step.

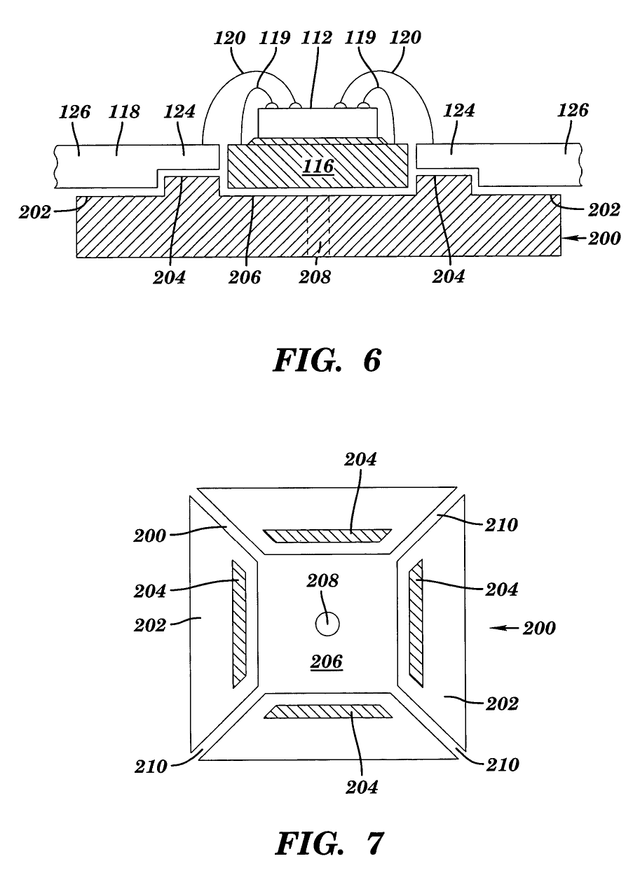

Turning to FIGS. 6-7, a heater block 200 for use in interconnecting first portion 124 to chip 112 via wire bonds 120 and chip 112 to die paddle 116 via wire bonds 119 is shown. Due to the reduction in thickness of first portion 124, conventional heater blocks do not sufficiently support and heat the end of the lead frame during connection of wire bonds 120. In order to address this problem, the present invention provides a heater block 200. Heater block 200 includes a support section 202 for supporting second portion 126 of metal lead 118 and the rest of electronic package 110. In addition, heater block 200 includes a raised heating section 204 that extends above first section 202 to contact first portion 124. Raised heating section 204 is coupled to a source of electricity in any now known or later developed fashion such that section 204 can provide sufficient heat to bond wires 120 thereto. Heater block 200 may also include a die pad support section 206 that is substantially planar with support section 202. Die pad support section 206 includes a vacuum opening 208 for holding metal layer 116 thereto. As shown in FIG. 7, heater block 200 may also include any required tiebar positioning elements 210 necessary to accommodate electronic package 110 during fabrication. As one with skill in the art will recognize, the configuration of tiebar postioning elements 210 and raised heating section 204 may vary depending on the desired layout of leads 118.

Finally, at least a portion of chip 112, the surface 130 of metal layer 116 and first portion 124 of metal lead 118 are encapsulated in polymeric material 122. Second portion 126 remains exposed by polymeric material 122, as described above. Optional steps include electrically interconnecting metal layer 116 to chip 112 prior to the step of encapsulation. It should be recognized that the particular order of steps described above may be altered and not depart from the scope of the invention.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

What is claimed is:

1. An electronic package having a mounted semiconductor chip and a polymeric material, the electronic package comprising:
a metal lead having a first portion that is unexposed on a surface of the package by the polymeric material and a second portion that is exposed, the first portion having a thickness that is less than the second portion, and wherein the first portion extends no less than approximately 0.7 mm and no greater than approximately 1.0 mm from the second portion; and
an electrical interconnection from the first portion to the semiconductor chip.

2. The electronic package of claim 1, wherein the semiconductor chip is mounted upon a metal layer via an adhesive.

3. The electronic package of claim 2, further comprising an electrical interconnection from the metal layer to the semiconductor chip.

4. The electronic package of claim 1, wherein the first portion is formed by etching the metal lead.

5. The electronic package of claim 1, wherein the first portion has a thickness that is no less than approximately 40% of the second portion, and wherein the first portion has a thickness that is no larger than approximately 85% of the second portion.

6. The electronic package of claim 5, wherein the first portion is approximately 50% of the thickness of the second portion.

7. The electronic package of claim 1, wherein the electrical interconnection is a wire bond.

8. The electronic package of claim 8, wherein the wire bond is no greater than approximately 4.0 mm.

9. The electronic package of claim 1, wherein the second portion has a length of no less than 0.35 mm and no greater than 0.45 mm.

10. A method of forming an electronic package, the method comprising the steps of:
providing a semiconductor chip mounted to a surface of a metal layer by an adhesive;
reducing the thickness of a metal lead such that the metal lead includes a first portion having a thickness that is less than a second portion;
electrically interconnecting the first portion to the semiconductor chip by placing a wire bond to the first portion and heating the first portion with a heater block having a heating section extending above a support section; and
enclosing at least a portion of the semiconductor chip, the surface of the metal layer and the first portion of the metal lead in a polymeric material, whereby the second portion remains exposed by the polymeric material.

11. The method of claim 10, further comprising the step of electrically interconnecting the metal layer to the semiconductor chip prior to the step of enclosing.

12. The method of claim 10, wherein the step of reducing includes etching the first portion.

13. The method of claim 12, wherein the first portion extends no less than approximately 0.7 mm and no greater than approximately 1.0 mm from the second portion.

14. The method of claim 10, wherein the first portion has a thickness that is no less than approximately 40% of the second portion, and wherein the first portion has a thickness that is no larger than approximately 85% of the second portion.

15. The method of claim 14, wherein the first portion is approximately 50% of the thickness of the second portion.

16. A heater block for use in fabricating an electronic package having a lead having a first portion having a thickness that is less than a second portion thereof, the heater block comprising:
an electronic package support section for supporting the second portion; and
a raised heating section for heating the first portion, the raised heating section extending above the support section to be adjacent the first portion.

17. The heater block of claim 16, further comprising a plurality of tiebar positioning elements.

18. The heater block of claim 16, further comprising a die pad support section.

19. The heater block of claim 18, wherein the die pad support section includes a vacuum opening for application of a vacuum to a die paddle of the electronic package.

20. The heater block of claim 16, further comprising a support section for the second portion of the lead.
